(19) United States
(12) Patent Application Publication
(10) Pub. No.: US 2005/0239267 A1
(43) Pub. Date: Oct. 27, 2005

(54) Substrate manufacturing method

(75) Inventor: Shuji Tobashi, Hiratsuka-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/110,666

(22) Filed: Apr. 21, 2005

(30) Foreign Application Priority Data
Apr. 23, 2004 (JP) 2004-128803

(51) Int. Cl. H01L 21/477

(52) U.S. Cl. 438/455; 438/471; 438/476

(57) ABSTRACT

A substrate manufacturing method includes steps of preparing a bonded substrate stack formed by bonding a second substrate to a first substrate having an insulator at least on a surface, forming a gettering layer to capture a metal contamination on the surface of the bonded substrate stack to form a composite substrate stack, annealing the composite substrate stack, and removing the gettering layer from the composite substrate stack.

### FIELD OF THE INVENTION

The present invention relates to a substrate manufacturing method and, more particularly, to a method of manufacturing a substrate having a single-crystal silicon layer formed on an insulating layer.

### BACKGROUND OF THE INVENTION

Over the years many studies have been made to manufacture SOI substrates. Recently, an oxygen ion implantation method called SIMOX and a substrate bonding method are known as major SOI substrate manufacturing methods.

In the oxygen ion implantation method, oxygen ions are implanted into a single-crystal silicon substrate, and high-temperature annealing is performed at 1,300° C. or more to form a silicon oxide layer, thereby forming a SOI structure. The concentration of implanted oxygen ions is 1×10¹⁸ ions/cm² or more. Then, high-temperature annealing at 1,300° C. or more is required for forming a silicon oxide layer.

In the substrate bonding method, a semiconductor substrate and another semiconductor substrate having an insulator are bonded to form a bonded substrate stack.

Then, the bonded substrate stack is annealed to form a SOI structure. Annealing for bonding is performed at almost 300° C. to 1,000° C. or more. In addition, to form thin device formation region, the semiconductor substrate must be worked into a desired thickness.

Thus, thin film formation by polishing, grinding, selective etching, separation at the ion implantation layer, or wafer jet method is required. After the semiconductor substrate is worked into the desired thickness, annealing at about 300° C. to 1,200° C. is performed again as needed.

By working to form a thin film, the surface roughness of the semiconductor substrate tends to become greater than that of a conventionally used semiconductor substrate. Therefore, planarization by polishing or annealing as described in Japanese Patent Laid-Open No. 5-218053 is performed.

In the conventional SOI substrate manufacturing method, high-temperature annealing must be performed once or a plurality of times. In annealing at a high temperature, metal contamination from the atmospheric gas or the components of the annealing furnace in use poses a problem. For this reason, it is difficult to reduce metal contamination during annealing. Even when metal contamination can be reduced, an expensive refining apparatus or a large amount of expensive high-purity quartz material or high-purity silicon carbide material must be used to keep the atmospheric gas in use at a high purity. Hence, it is difficult to manufacture semiconductor substrates at a low cost.

To reduce a metal contamination in a single-crystal silicon substrate, normally, a method of capturing the metal contamination by forming a gettering site in the substrate is used. Gettering methods are roughly classified by the gettering portion into extrinsic gettering (EG) and intrinsic gettering (IG). In EG, a polysilicon film is formed on the lower surface of a single-crystal silicon substrate by CVD, or a heavily-doped layer of an impurity such as phosphorus is formed by diffusion or ion implantation, thereby forming a gettering layer. In IG, annealing is performed at a predetermined temperature to precipitate oxygen in a single-crystal silicon substrate, and the oxygen precipitation or minute defects such as stacking faults are introduced by the precipitation, thereby forming a gettering layer in the single-crystal silicon substrate. Generally, a metal contamination gettering effect of IG is greater than that of EG.

There are also application examples of IG and EG to a SOI semiconductor substrate, like the single-crystal silicon substrate. An example of EG is a method of forming a heavily-doped phosphorus diffusion layer on the lower surface of a SOI semiconductor substrate (Japanese Patent Laid-Open No. 8-116038). An example of IG is a method of introducing an oxygen precipitation and dislocation in a SOI semiconductor substrate (Japanese Patent Laid-Open No. 8-293589). As metal contamination gettering methods unique to a SOI semiconductor substrate, a method of forming a gettering layer in the interface between the active layer and insulating layer of a SOI semiconductor substrate (Japanese Patent Laid-Open No. 6-163862) and a method of forming a gettering layer in the interface between the insulating layer and a support substrate (Japanese Patent Laid-Open No. 8-316442) are disclosed.

However, when the metal contamination gettering layer is formed in the process of manufacturing the bonded SOI semiconductor substrate, the substrate is fed to the semiconductor device manufacturing process while keeping metal contamination left in the gettering layer in the manufacturing process. In the annealing process in manufacturing a semiconductor device, metal contamination in the gettering layer can be diffused into the SOI semiconductor substrate again to inversely contaminate it depending on the temperature of annealing. This leads to a decrease in manufacturing yield of semiconductor devices.

### SUMMARY OF THE INVENTION

The present invention has been made in consideration of the above problems, and has as its object to reduce a metal contamination contained in a substrate.

According to the first aspect of the present invention, there is provided a substrate manufacturing method comprising steps of preparing a bonded substrate stack formed by bonding a second substrate to a first substrate having an insulator at least on a surface, forming a gettering layer to capture a metal contamination on a surface of the bonded substrate stack to form a composite substrate stack, annealing the composite substrate stack, and removing the gettering layer from the composite substrate stack.

According to the second aspect of the present invention, there is provided a substrate manufacturing method comprising steps of preparing a first substrate which has an insulator at least on a surface and a second substrate in which a gettering layer to capture a metal contamination is formed on a surface, bonding the first substrate and second substrate while arranging the gettering layer on a surface to form a composite substrate stack, annealing the composite substrate stack, and removing the gettering layer from the composite substrate stack.

According to the present invention, a metal contamination contained in a substrate can be reduced.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A to 1G are views showing a substrate manufacturing method according to the first embodiment of the present invention;

FIGS. 2A to 2H are views showing a substrate manufacturing method according to the second embodiment of the present invention;

FIGS. 3A to 3H are views showing a substrate manufacturing method according to the third embodiment of the present invention;

FIGS. 4A to 4I are views showing a substrate manufacturing method according to the fourth embodiment of the present invention; and

FIGS. 5A to 5E are views showing an application example of the substrate manufacturing methods according to the first to fourth embodiments.

### DETAILED DESCRIPTION OF THE PREFERRED EMBODIMENTS

[First Embodiment]

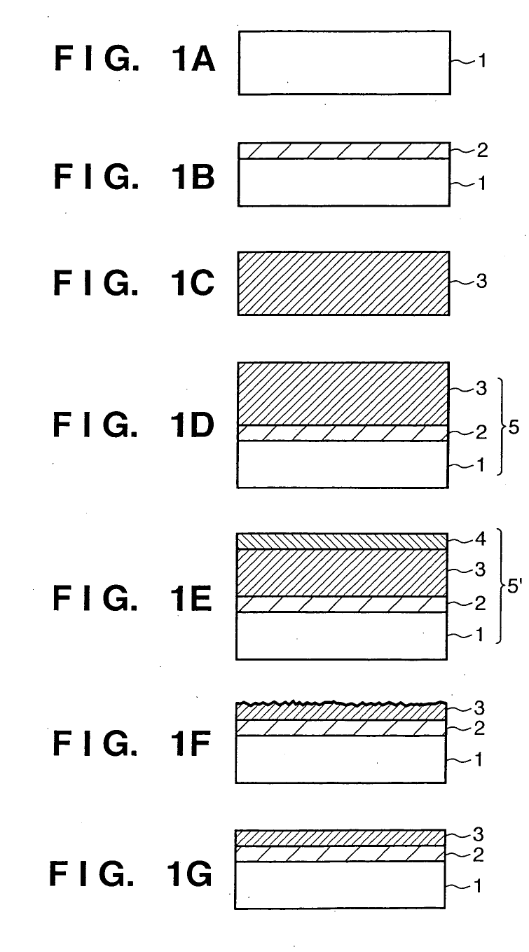

FIGS. 1A to 1G are views showing a substrate manufacturing method according to the first embodiment of the present invention.

As the substrate manufacturing method according to the first embodiment of the present invention, a method of manufacturing a substrate such as a SOI substrate will be described as an example. FIGS. 1A to 1G are views for explaining the substrate manufacturing method according to the preferred embodiment of the present invention.

In the step shown in FIG. 1A, a first semiconductor substrate (support substrate) 1 is prepared. As the first semiconductor substrate 1, a substrate containing Si, Ge, SiGe, SiC, C, GaAs, GaN, AlGaAs, InGaAs, InP, or InAsSi, a substrate obtained by forming an insulator on these substrates, a transparent substrate such as a quartz substrate, or a sapphire substrate can be used.

In the step shown in FIG. 1B, an insulating layer 2 is formed on the first semiconductor substrate (support substrate) 1. As the insulating material of the insulating layer 2, for example, silicon oxide, silicon nitride, silicon oxynitride, aluminum oxide, tantalum oxide, hafnium oxide, titanium oxide, scandium oxide, yttrium oxide, gadolinium oxide, lanthanum oxide, zirconium oxide, or a glass mixture thereof can be used. The insulating layer 2 can be formed by, e.g., oxidizing the surface of the first semiconductor substrate 1 or depositing an insulating material by CVD or PVD. When the first semiconductor substrate 1 or a second semiconductor substrate 3 contains an insulator in the surface, the step shown in FIG. 1B can be omitted.

In the step shown in FIG. 1C, the second semiconductor substrate 3 is prepared. As the second semiconductor substrate 3, a substrate containing Si, Ge, SiGe, SiC, C, GaAs, GaN, AlGaAs, InGaAs, InP, or InAs or a substrate obtained by forming an insulator on these substrates can be used. However, the second semiconductor substrate 3 needs to have a sufficiently flat surface to be bonded and can be of any other type.

In the step shown in FIG, 1D, the first semiconductor substrate 1 and second semiconductor substrate 3 are bonded at room temperature while making the second semiconductor substrate 3 face the insulating layer 2, thereby forming a bonded substrate stack 5. The insulating layer 2 can be formed on the first semiconductor substrate 1, on the second semiconductor substrate 3, or on both of them. It is necessary that the state shown in FIG. 1D should be obtained when the first semiconductor substrate 1 is bonded to the second semiconductor substrate 3. After the first semiconductor substrate 1 and second semiconductor substrate 3 are completely bonded, a process to increase the bonding strength is preferably performed. In addition to or in place of this process, at least one of anodic bonding, pressing, and bonding by an adhesive may be performed.

In the step shown in FIG. 1E, a gettering layer 4 including a gettering site to capture an internal metal contamination is formed on the exposed surface of the second semiconductor substrate 3 serving as an active layer, thereby forming a composite substrate stack 5′. The gettering layer 4 can be formed by, e.g., (1) forming a polysilicon film, amorphous silicon film, silicon nitride film, or a combination thereof on the surface of the semiconductor substrate using CVD (Chemical Vapor Deposition), (2) thermally diffusing an impurity such as P, B, or As in the semiconductor substrate, (3) ion-implanting P, B, As, C, Si, O, or Ar into the semiconductor substrate, or (4) irradiating the semiconductor substrate surface with laser. In addition, annealing to increase the bonding strength is performed for the composite substrate stack 5′ having the gettering layer 4. The annealing temperature can be equal to or lower than the melting point of the semiconductor substrate. With this annealing, the metal contamination in the composite substrate stack 5′ is diffused and captured by the gettering site in the gettering layer 4. Annealing to diffuse the metal contamination in the gettering layer 4 is preferably performed substantially in the same step as the annealing to increase the bonding strength and, more preferably, in a single apparatus.

In the step shown in FIG. 1F, the gettering layer 4 formed on the exposed surface on the side of the second semiconductor substrate 3 of the composite substrate stack 5′ is removed. In addition, the second semiconductor substrate 3 serving as the active layer is removed to a desired thickness. For this removing step, for example, wet etching using mixed acid containing hydrofluoric acid or an alkali solution, dry etching, mechanochemical polishing using a free abrasive grain, grinding using a fixed abrasive grain, separation at an ion implantation layer formed by ion implantation, or separation by wafer jet disclosed in Japanese Patent Laid-Open No. 11-005064 can be used. With this process, the metal contamination sticking to or mixed in the composite substrate stack 5′ from the atmospheric gas or the components of the annealing furnace used in annealing in the step shown in FIG. 1E can be removed. As a consequence, the metal contamination captured by the gettering layer can be prevented from diffusing in the SOI semiconductor substrate again and inversely contaminating it by annealing in the subsequent semiconductor device manufacturing process.

In the step shown in FIG. 1G, the surface of the composite substrate stack 5′ is planarized. This planarization is implemented by, e.g., performing high-temperature annealing in a reducing atmosphere, inert gas atmosphere, or a gas mixture atmosphere of them. For example, an atmosphere containing hydrogen gas can be used as the reducing atmosphere, and an atmosphere containing hydrogen gas can be used as the inert gas atmosphere. The temperature of the high-temperature annealing is preferably set within the range of 800° C. to 1,300° C.

In this embodiment, the gettering layer 4 is formed after the bonded substrate stack 5 is formed. However, the present invention is not limited to this. The gettering layer 4 may be formed before the bonded substrate stack 5 is formed. In this case, the gettering layer can be formed on the second semiconductor substrate 3 in advance.

As described above, according to this embodiment, the gettering layer and the semiconductor substrate under it are successively removed. The metal contamination sticking to or mixed in the semiconductor substrate until bonding and annealing of the bonded substrate stack can effectively be removed without adding any new step to the original semiconductor substrate removing step.

[Second Embodiment]

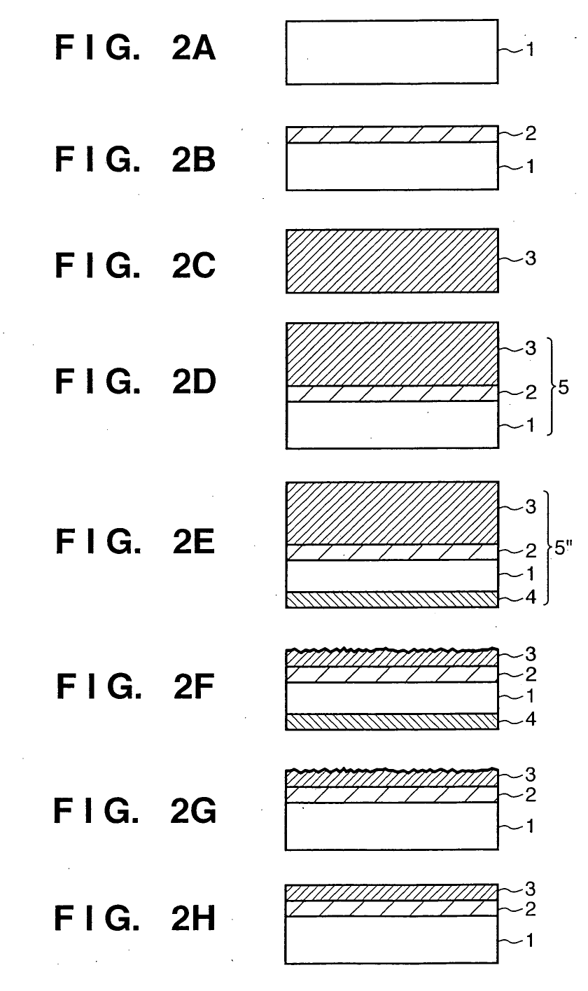

FIGS. 2A to 2H are views showing a substrate manufacturing method according to the second embodiment of the present invention.

As the substrate manufacturing method according to the second embodiment of the present invention, a method of manufacturing a substrate such as a SOI substrate will be described as an example. FIGS. 2A to 2H are views for explaining the substrate manufacturing method according to the preferred embodiment of the present invention. The same reference numerals as in FIGS. 1A to 1G denote the same or similar elements in FIGS. 2A to 2H.

The steps shown in FIGS. 2A to 2D are substantially the same as those shown in FIGS. 1A to 1D in the substrate manufacturing method according to the first embodiment.

In the step shown in FIG. 2E, a gettering layer 4 having a gettering site to capture an internal metal contamination is formed on the exposed surface on the side of a first semiconductor substrate 1 serving as a support substrate, thereby forming a composite substrate stack 5″. In the first embodiment, the gettering layer 4 is formed on the exposed surface on the side of the second semiconductor substrate 3. The second embodiment is different from the first embodiment in that the gettering layer 4 is formed on the exposed surface of the composite substrate stack 5″ on the side of the first semiconductor substrate 1. The material and forming method of the gettering layer 4 are the same as in the first embodiment. Next, as in the first embodiment, annealing to increase the bonding strength is performed for the composite substrate stack 5″ having the gettering layer 4. The annealing temperature needs to be from 300° C. (inclusive) to the melting point (inclusive) of the semiconductor substrate. With this annealing, the metal contamination in the composite substrate stack 5″ is diffused and captured by the gettering site in the gettering layer 4.

In the step shown in FIG. 2F, a second semiconductor substrate 3 serving as an active layer is removed to a desired thickness. This removing step can be implemented by substantially the same method as in FIG. 1F.

In the step shown in FIG. 2G, the gettering layer 4 formed on the exposed surface on the side of the first semiconductor substrate 1 is removed. This removing step can be implemented by substantially the same method as in FIG. 2F.

With this process, the metal contamination sticking to or mixed in the composite substrate stack 5″ from the atmospheric gas or the components of the annealing furnace used in annealing in the step shown in FIG. 2E can be removed. Hence, the metal contamination captured by the gettering layer can be prevented from diffusing in the SOI semiconductor substrate again and inversely contaminating it by annealing in the subsequent semiconductor device manufacturing process.

In the step shown in FIG. 2H, the surface of the composite substrate stack 5″ on the side of the second semiconductor substrate 3 is planarized. This planarization can be implemented by substantially the same method as in FIG. 1G.

As described above, according to this embodiment, the gettering layer is removed after the second semiconductor substrate serving as the active layer is removed. With this method, the metal contamination sticking to or mixed in the semiconductor substrate until the second semiconductor substrate removing step can effectively be removed.

[Third Embodiment]

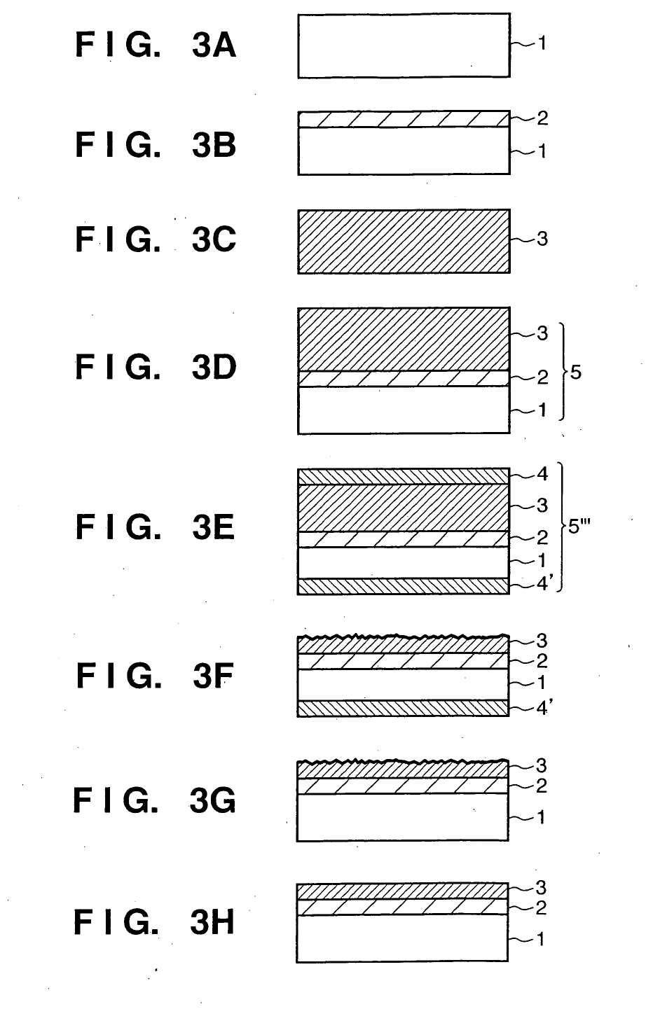

FIGS. 3A to 3H are views showing a substrate manufacturing method according to the third embodiment of the present invention.

As the substrate manufacturing method according to the third embodiment of the present invention, a method of manufacturing a substrate such as a SOI substrate will be described as an example. FIGS. 3A to 3H are views for explaining the substrate manufacturing method according to the preferred embodiment of the present invention. The same reference numerals as in FIGS. 1A to 1G and 2A to 2H denote the same or similar elements in FIGS. 3A to 3H.

The steps shown in FIGS. 3A to 3D are substantially the same as those shown in FIGS. 1A to 1D in the substrate manufacturing method according to the first embodiment.

In the step shown in FIG. 3E, gettering layers 4 and 4′ each having a gettering site to capture an internal metal contamination are formed on the surface on the side of a second semiconductor substrate 3 serving as an active layer and the exposed surface on the side of a first semiconductor substrate 1 serving as a support substrate, respectively, thereby forming a composite substrate stack 5′″. In the first embodiment, the gettering layer 4 is formed on the exposed surface on the side of the second semiconductor substrate 3. In the second embodiment, the gettering layer 4 is formed on the exposed surface on the side of the first semiconductor substrate 1. The third embodiment is different from these embodiments in that the gettering layers 4 and 4′ are formed on the surfaces of the first semiconductor substrate 1 and second semiconductor substrate 3, respectively. The material and forming method of the gettering layers 4 and 4′ are the same as in the first and second embodiments. Then, as in the first and second embodiments, annealing to increase the bonding strength is performed for the composite substrate stack 5′″ having the gettering layers 4 and 4′. The annealing temperature needs to be from 300° C. (inclusive) to the melting point (inclusive) of the semiconductor substrate. With this annealing, the metal contamination in the composite substrate stack 5′″ is diffused and captured by the gettering sites in the gettering layers 4 and 4′. In this embodiment, since the gettering layers 4 and 4′ are formed on both surfaces of the composite substrate stack 5′″, a larger amount of metal contamination can be captured.

In the step shown in FIG. 3F, the gettering layer 4′ formed on the exposed surface of the composite substrate stack 5′″ on the side of the second semiconductor substrate 3 is removed. In addition, the second semiconductor substrate 3 serving as the active layer is removed to a desired thickness. This removing step can be implemented by substantially the same method as in FIG. 1F.

In the step shown in FIG. 3G, the gettering layer 4′ formed on the exposed surface of the composite substrate stack 5′″ on the side of the first semiconductor substrate 1 is removed.

When the gettering layers 4 and 4′ are removed in the steps shown in FIGS. 3F and 3G, the metal contamination sticking to or mixed in the composite substrate stack 5′″ from the atmospheric gas or the components of the annealing furnace used in annealing in the step shown in FIG. 3E can be removed. Hence, the metal contamination captured by the gettering layer can be prevented from diffusing in the SOI semiconductor substrate again and inversely contaminating it by annealing in the subsequent semiconductor device manufacturing process. In this embodiment, since the gettering layers 4 and 4′ are formed on both surfaces of the composite substrate stack 5′″, a larger amount of metal contamination is captured by the gettering layers 4 and 4′. When both the gettering layers 4 and 4′ are removed, a larger amount of metal contamination can be removed.

In the step shown in FIG. 3H, the surface of the composite substrate stack 5′″ on the side of the second semiconductor substrate 3 is planarized. This planarization can be implemented by substantially the same method as in FIG. 1G.

As described above, according to this embodiment, since the gettering layers are formed on both surfaces of the bonded substrate stack, the metal contamination removing capability can be increased.

[Fourth Embodiment]

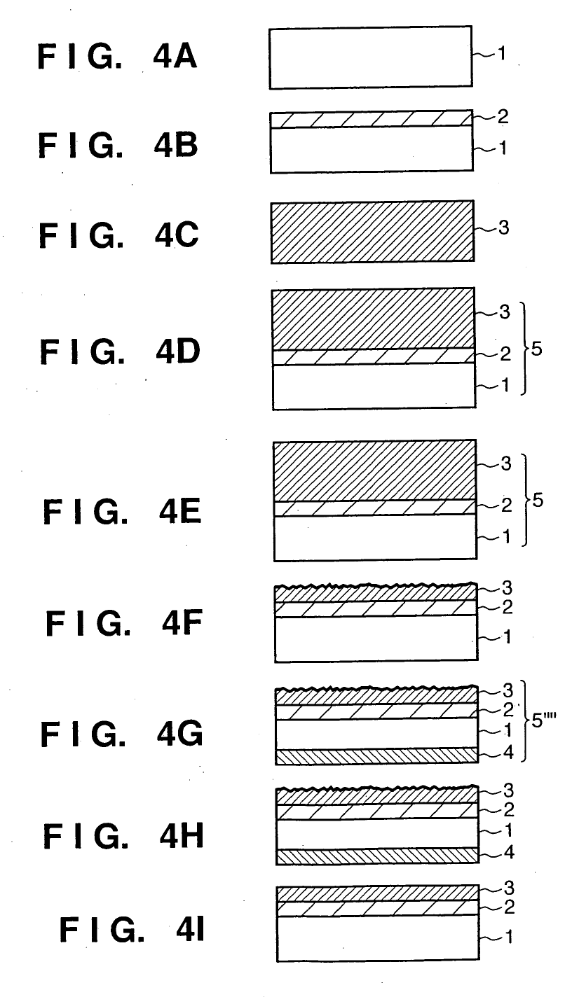

FIGS. 4A to 4I are views showing a substrate manufacturing method according to the fourth embodiment of the present invention.

As the substrate manufacturing method according to the fourth embodiment of the present invention, a method of manufacturing a substrate such as a SOI substrate will be described as an example. FIGS. 4A to 4I are views for explaining the substrate manufacturing method according to the preferred embodiment of the present invention. The same reference numerals as in FIGS. 1A to 3H denote the same or similar elements in FIGS. 4A to 4I.

The steps shown in FIGS. 4A to 4D are substantially the same as those shown in FIGS. 1A to 1D in the substrate manufacturing method according to the first embodiment.

In the step shown in FIG. 4E, annealing to increase the bonding strength is performed for a bonded substrate stack 5. The annealing temperature needs to be from 300° C. (inclusive) to the melting point (inclusive) of the semiconductor substrate.

In the step shown in FIG. 4F, a second semiconductor substrate 3 serving as an active layer is removed to a desired thickness. This removing step can be implemented by substantially the same method as in FIG. 1F.

In the step shown in FIG. 4G, a gettering layer 4 having a gettering site to capture an internal metal contamination is formed on the exposed surface on the side of a first semiconductor substrate 1 serving as a support substrate, thereby forming a composite substrate stack 5″″. The fourth embodiment is different from the first to third embodiments in that the gettering layer 4 is formed after the second semiconductor substrate 3 is removed to the desired thickness. The material and forming method of the gettering layer 4 are the same as in the first to third embodiments.

In the step shown in FIG. 4H, annealing is performed for the composite substrate stack 5″″. With this annealing, the surface of the composite substrate stack 5″″ on the side of the first semiconductor substrate 1 is planarized. This planarization can be implemented by substantially the same method as in FIG. 1G. In addition, with this annealing, the metal contamination in the SOI semiconductor substrate is diffused again and captured by the gettering sites in the gettering layer 4.

In the step shown in FIG. 4I, the gettering layer 4 formed on the exposed surface of the composite substrate stack 5″″ on the side of the first semiconductor substrate 1 is removed. The removing method of the gettering layer 4 is substantially the same as in the first to third embodiments.

With this process, the metal contamination sticking to or mixed in the bonded substrate stack 5 from the atmospheric gas or the components of the annealing furnace used in annealing in the step shown in FIG. 4H can be removed. Hence, the metal contamination captured by the gettering layer can be prevented from diffusing in the SOI semiconductor substrate again and inversely contaminating it by annealing in the subsequent semiconductor device manufacturing process.

As described above, according to this embodiment, the gettering layer is removed after the surface of he first semiconductor substrate serving as the support substrate is planarized. With this method, the metal contamination sticking to or mixed in the semiconductor substrate until the surface of the first semiconductor substrate is planarized can effectively be removed.

According to the first to fourth embodiments, metal contamination from the atmospheric gas or the components of the annealing furnace in the high-temperature annealing can be reduced. As a result, neither expensive refining apparatus nor large amount of expensive high-purity quartz material or high-purity silicon carbide material need be used to keep the atmospheric gas in use at a high purity. Hence, semiconductor substrates can be manufactured and provided at a low cost.

### APPLICATION EXAMPLES

A bonded SOI substrate stack manufacturing process using the substrate manufacturing methods according to the first to fourth embodiments of the present invention will be described next as an application example.

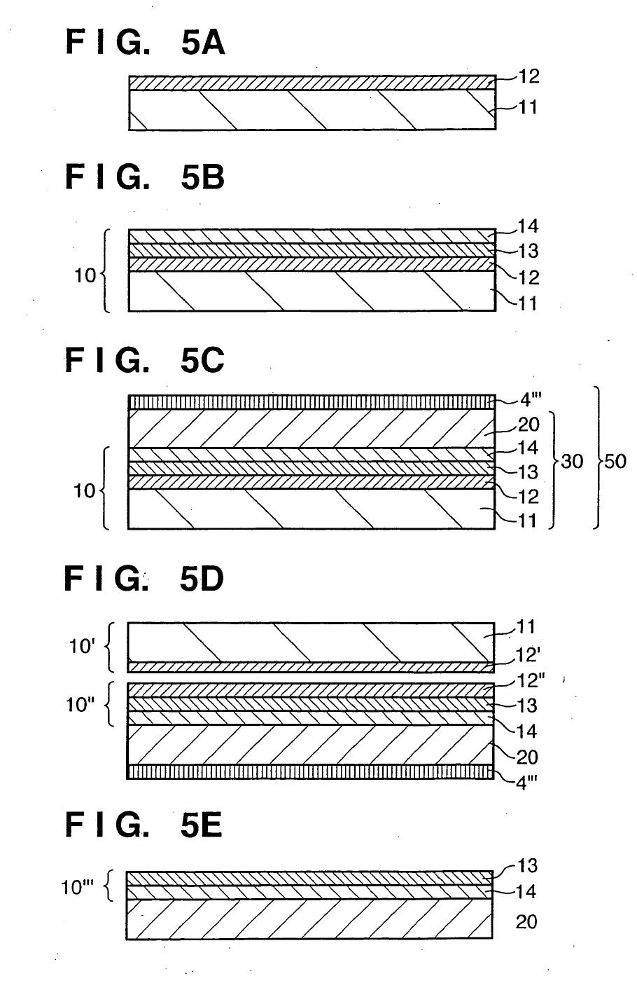

FIGS. 5A to 5E are views showing the bonded SOI substrate stack manufacturing process using the substrate manufacturing methods according to the first to fourth embodiments of the present invention. The same reference numerals as in FIGS. 1A to 1G denote the same or similar elements in FIGS. 5A to 5E.

In the step shown in FIG. 5A, a single-crystal Si substrate 11 to form a first substrate (seed wafer) 10 is prepared. A porous Si layer 12 serving as a separation layer is formed on the major surface of the first substrate 10 using the above-described anodizing apparatus. The porous Si layer 12 can be formed by, e.g., performing anodizing (anodic treatment) for the single-crystal Si substrate 11 in an electrolytic solution (chemical solution).

As the electrolytic solution, for example, a solution containing hydrogen fluoride, a solution containing hydrogen fluoride and ethanol, or a solution containing hydrogen fluoride and isopropyl alcohol can be used. More specifically, as the electrolytic solution, a solution mixture of, e.g., an HF solution (HF concentration=49 wt %) and ethanol at a volume ratio of 2:1 is suitable.

The porous Si layer 12 may have a multilayered structure including at least two layers having different porosities. The porous Si layer 12 having the multilayered structure preferably includes a first porous Si layer having a first porosity on the surface side and, under it, a second porous Si layer having a second porosity higher than the first porosity. When such a multilayered structure is employed, in the subsequent step of forming a non-porous layer 13, the non-porous layer 13 with few defects can be formed on the first porous Si layer. In addition, the bonded substrate stack can be separated at a desired position in the separation step later. The first porosity is preferably 10% to 30% and, more preferably, 15% to 25%. The second porosity is preferably 35% to 70% and, more preferably, 40% to 60%.

When the above-described solution mixture (hydrofluoric acid with HF concentration of 49 wt % ethanol=2:1) is used, for example, the first layer (surface side) is preferably generated at a current density of 8 mA/cm² for a process time of 5 to 11 min, and the second layer (inner side) is preferably generated at a current density of 23 to 33 mA/cm² for a process time of 80 sec to 2 min.

At the first stage of the step shown in FIG. 5B, the first non-porous layer 13 is formed on the porous Si layer 12. As the first non-porous layer 13, an Si layer such as a single-crystal Si layer, polysilicon layer, or amorphous Si layer, a Ge layer, SiGe layer, SiC layer, C layer, GaAs layer, GaN layer, AlGaAs layer, InGaAs layer, InP layer, or InAs layer is suitable.

At the second stage of the step shown in FIG. 5B, an SiO₂ layer (insulating layer) 14 is formed as the second non-porous layer on the first non-porous layer 13. With this process, the first substrate 10 is obtained. The SiO₂ layer 14 can be formed in, e.g., an O₂/H₂ atmosphere at 1,100° C. for 10 to 33 min.

At the first stage of the step shown in FIG. 5C, a second substrate (handle wafer) 20 is prepared. The first substrate 10 and second substrate 20 are bonded at room temperature while making the second substrate 20 face the insulating layer 14, thereby forming a bonded substrate stack 30.

The insulating layer 14 can be formed on the side of the single-crystal Si layer 13, as described above, on the second substrate 20, or on both of them. It is necessary that the state shown in FIG. 5C should be obtained when the first substrate is bonded to the second substrate. However, when the insulating layer 14 is formed on the side of the first non-porous layer (e.g., single-crystal Si layer) 13 serving as an active layer, as described above, the bonding interface between the first substrate 10 and the second substrate 20 can be spaced apart from the active layer. Hence, a semiconductor substrate such as a SOI substrate having a higher quality can be obtained.

As the second substrate 20, an Si substrate, a substrate obtained by forming an SiO₂ layer on an Si substrate, a transparent substrate such as a quartz substrate, or a sapphire substrate is suitable. However, the second substrate 20 needs to have a sufficiently flat surface to be bonded and can be of any other type.

At the second stage of the step shown in FIG. 5C, a gettering layer 4′″ having a gettering site to capture an internal metal contamination is formed on the exposed surface of the bonded substrate stack 30 on the side of the second substrate 20, thereby forming a composite substrate stack 50. The step of forming the gettering layer 4′″ can be implemented as in FIG. 1E.

After the substrates 10 and 20 are completely bonded, a process to increase the bonding strength is preferably performed. The annealing temperature needs to be from 300° C. (inclusive) to the melting point (inclusive) of the semiconductor substrate. An example of this process, 1) annealing is performed in an N₂ atmosphere at 1,100° C. for 10 min, and 2) annealing (oxidation) is performed in an O₂/H₂ atmosphere at 1,100° C. for 50 to 100 min. In addition to or in place of this process, anodic bonding and/or pressing may be performed. With this annealing, the metal contamination in the bonded substrate stack 30 is diffused and captured by the gettering site in the gettering layer 4′″. Annealing in forming the gettering layer 4′″ is preferably performed substantially in substantially the same step as the process to increase the bonding strength between the substrates 10 and 20 and, more preferably, in a single apparatus.

At the first stage of the step shown in FIG. 5D, the composite substrate stack 50 is separated at the portion of the porous layer 12 having a low mechanical strength. Various kinds of methods can be employed for separation. A method using a fluid is preferably used. For example, a fluid is injected into the porous layer 12, or a static pressure is applied to the porous layer 12 by a fluid.

With this separation step, the transfer layer (non-porous layer 13 and insulating layer 14) of the first substrate 10 is transferred onto the second substrate 20. When only the non-porous layer 13 is formed on the porous layer 12 of the first substrate 10, the transfer layer includes only the non-porous layer 13.

At the second stage of the step shown in FIG. 5D, the gettering layer 4′″ is removed. For this removing step, for example, wet etching using mixed acid containing hydrofluoric acid or an alkali solution, dry etching, mechanochemical polishing using a free abrasive grain, grinding using a fixed abrasive grain, separation at an ion implantation layer formed by ion implantation, or separation by wafer jet disclosed in Japanese Patent Laid-Open No. 11-005064 can be used.

With this process, the metal contamination sticking to or mixed in the bonded substrate stack 30 or composite substrate stack 50 from the atmospheric gas or the components of the annealing furnace used in annealing in the step shown in FIG. 5C can be removed. The metal contamination captured by the gettering layer can be prevented from diffusing in the SOI semiconductor substrate again and inversely contaminating it by annealing in the subsequent semiconductor device manufacturing process.

In the step shown in FIG. 5E, a porous layer 12″ on the second substrate 20 after separation is selectively removed by etching. A substrate having the non-porous layer 13 on the insulating layer 14 is obtained. When the non-porous layer 13 is a semiconductor layer, it is called a SOI (Semiconductor On Insulator or Silicon On Insulator) layer. A substrate having a SOI layer is called a SOI substrate.

A porous layer 12′ on the single-crystal Si substrate 11 of a first substrate 10′ after separation is selectively removed by etching. The single-crystal Si substrate 11 obtained in this way can be used again as a substrate to form the first substrate 10 or the second substrate 20.

In this application example, the gettering layer 4′″ is formed on the side of the second substrate 20. However, the present invention is not limited to this. The gettering layer may be formed on the side of the first substrate 10 or on the surfaces of both the first substrate 10 and second substrate 20. The steps of forming and removing the gettering layer 4′″ are not limited to those described in this application example. Various changes and modifications can be made for these steps.

The present invention will be described below on the basis of examples. However, the present invention is not limited to these examples.

### Example 1

FIGS. 1A to 1G are views showing Example 1. As a first semiconductor substrate (support substrate) 1, a single-crystal silicon wafer having a diameter of 8 inches, a crystal orientation of (100), and a thickness of 725 μm was prepared (corresponding to FIG. 1A). Thermal oxidation was performed at 1,000° C. for 45 min to form a 200-nm SiO₂ layer 2 on the surface of the first semiconductor substrate 1 (corresponding to FIG. 1B). As a second semiconductor substrate 3, a single-crystal silicon wafer 3 having a crystal orientation of (100) and a thickness of 725 μm was prepared (corresponding to FIG. 1C) and bonded to the first semiconductor substrate 1 (corresponding to FIG. 1D). The structure was introduced into an annealing furnace for bonding. Phosphorus having a concentration of 1×10²⁰ atoms/cm³ was gas-diffused in the lower surface of the second semiconductor substrate 3. Then, annealing was performed at 1,100° C. for 1 hr to obtain a heavily-doped phosphorus layer 4 (corresponding to FIG. 1E). The thickness of the two bonded semiconductor substrates was reduced to 730 μm by grinding from the lower surface side of the second semiconductor substrate 3 (corresponding to FIG. 1F). Annealing was performed in an atmosphere containing hydrogen gas at 1,100° C. for 1 hr (corresponding to FIG. 1G). According to Example 1, the metal contamination in the semiconductor substrate could effectively be removed.

### Example 2

FIGS. 2A to 2H are views showing Example 2. As a first semiconductor substrate (support substrate) 1, a single-crystal silicon wafer having a diameter of 8 inches, a crystal orientation of (100), and a thickness of 725 μm was prepared (corresponding to FIG. 2A). Thermal oxidation was performed at 1,000° C. for 45 min to form a 200-nm SiO₂ layer 2 on the surface of the first semiconductor substrate 1 (corresponding to FIG. 2B). As a second semiconductor substrate 3, a single-crystal silicon wafer 3 having a crystal orientation of (100) and a thickness of 725 μm was prepared (corresponding to FIG. 2C) and bonded to the first semiconductor substrate 1 (corresponding to FIG. 2D). The structure was introduced into an annealing furnace for bonding. Phosphorus having a concentration of 1×10¹⁵ atoms/cm³ was ion-implanted in the lower surface of the first semiconductor substrate 1. Then, annealing was performed at 1,100° C. for 1 hr to obtain a heavily-doped phosphorus layer 4 (corresponding to FIG. 2E). The thickness of the two bonded semiconductor substrates was reduced to 730 μm by grinding from the lower surface side of the second semiconductor substrate 3 (corresponding to FIG. 2F). The heavily-doped phosphorus layer formed on the lower surface of the first semiconductor substrate 1 was removed using KOH solution (corresponding to FIG. 2G). Annealing was performed in an atmosphere containing hydrogen gas at 1,100° C. for 1 hr (corresponding to FIG. 2H). According to Example 2, the metal contamination in the semiconductor substrate until grinding from the lower surface side of the second semiconductor substrate 3 could effectively be removed.

### Example 3

FIGS. 3A to 3H are views showing Example 3. As a first semiconductor substrate (support substrate) 1, a single-crystal silicon wafer having a diameter of 8 inches, a crystal orientation of (100), and a thickness of 725 μm was prepared (corresponding to FIG. 3A). Thermal oxidation was performed at 1,000° C. for 45 min to form a 200-nm SiO₂ layer 2 on the surface of the first semiconductor substrate 1 (corresponding to FIG. 3B). As a second semiconductor substrate 3, a single-crystal silicon wafer 3 having a crystal orientation of (100) and a thickness of 725 μm was prepared (corresponding to FIG. 3C) and bonded to the first semiconductor substrate 1 (corresponding to FIG. 3D). The structure was introduced into an annealing furnace for bonding. Phosphorus having a concentration of 1×10²⁰ atoms/cm³ was gas-diffused in the lower surfaces of the first semiconductor substrate 1 and second semiconductor substrate 3. Then, annealing was performed at 1,100° C. for 1 hr to obtain heavily-doped phosphorus layers 4 and 4′ (corresponding to FIG. 3E). The thickness of the two bonded semiconductor substrates was reduced to 730 μm by grinding from the lower surface side of the second semiconductor substrate 3 (corresponding to FIG. 3F). The heavily-doped phosphorus layer 4′ formed on the lower surface of the first semiconductor substrate 1 was removed using KOH solution (corresponding to FIG. 3G). Annealing was performed in an atmosphere containing hydrogen gas at 1,100° C. for 1 hr (corresponding to FIG. 3H). According to Example 3, the metal contamination could effectively be removed from both sides of the substrate.

### Example 4

FIGS. 4A to 4I are views showing Example 4. As a first semiconductor substrate (support substrate) 1, a single-crystal silicon wafer having a diameter of 8 inches, a crystal orientation of (100), and a thickness of 725 μm was prepared (corresponding to FIG. 4A). Thermal oxidation was performed at 1,000° C. for 45 min to form a 200-nm SiO₂ layer 2 on the surface of the first semiconductor substrate 1 (corresponding to FIG. 4B). As a second semiconductor substrate 3, a single-crystal silicon wafer 3 having a crystal orientation of (100) and a thickness of 725 μm was prepared (corresponding to FIG. 4C) and bonded to the first semiconductor substrate 1 (corresponding to FIG. 4D). The structure was introduced into an annealing furnace for bonding. Annealing was performed at 1,100° C. for 1 hr (corresponding to FIG. 4E). The thickness of the two bonded semiconductor substrates was reduced to 730 μm by grinding from the lower surface side of the second semiconductor substrate 3 (corresponding to FIG. 4F). Phosphorus having a concentration of 1×10¹⁵ atoms/cm was ion-implanted in the lower surface of the first semiconductor substrate 1. Then, annealing was performed at 1,100° C. for 1 hr to obtain a heavily-doped phosphorus layer 4 (corresponding to FIG. 4G). Annealing was performed in an atmosphere containing hydrogen gas at 1,100° C. for 1 hr (corresponding to FIG. 4H). The heavily-doped phosphorus layer formed on the lower surface of the first semiconductor substrate 1 was removed using KOH solution (corresponding to FIG. 4I). According to Example 4, the metal contamination in the semiconductor substrate until annealing was performed in the atmosphere containing hydrogen gas could effectively be removed.

As many apparently widely different embodiments of the present invention can be made without departing from the spirit and scope thereof, it is to be understood that the invention is not limited to the specific embodiments thereof except as defined in the claims.

### CLAIM OF PRIORITY

This application claims priority from Japanese Patent Application No. 2004-128803 filed Apr. 23, 2004, which is hereby incorporated by reference herein.

1. A substrate manufacturing method comprising steps of:
preparing a bonded substrate stack formed by bonding a second substrate to a first substrate having an insulator at least on a surface;
forming a gettering layer to capture a metal contamination on a surface of the bonded substrate stack to form a composite substrate stack;
annealing the composite substrate stack; and
removing the gettering layer from the composite substrate stack.

2. A method according to claim 1, wherein in the gettering layer formation step, the gettering layer is formed on an exposed surface of the bonded substrate stack on a side of the second substrate.

3. A method according to claim 2, further comprising, after the gettering layer removing step, a step of removing the second substrate to a desired thickness.

4. A method according to claim 1, wherein in the gettering layer formation step, the gettering layer is formed on an exposed surface of the bonded substrate stack on a side of the first substrate.

5. A method according to claim 1, wherein in the gettering layer formation step, the gettering layer is formed on each of exposed surfaces of the bonded substrate stack on sides of the first substrate and second substrate.

6. A method according to claim 5, wherein in the gettering layer removing step, the gettering layer formed on the exposed surface of the composite substrate stack on the side of the second substrate is removed.

7. A method according to claim 6, further comprising, after the gettering layer removing step, a step of removing the second substrate to a desired thickness.

8. A method according to claim 7, further comprising, after the second substrate removing step, a step of removing the gettering layer formed on the exposed surface of the composite substrate stack on the side of the first substrate.

9. A method according to claim 1, further comprising, after the gettering layer removing step, a step of annealing the composite substrate stack in one of a reducing atmosphere, an inert gas atmosphere, and a gas mixture atmosphere thereof.

10. A method according to claim 1, further comprising, after the bonded substrate stack preparation step before the gettering layer formation step, a step of annealing the bonded substrate stack.

11. A method according to claim 10, further comprising, after the annealing step before the gettering layer formation step, a step of removing a surface of the second substrate included in the bonded substrate stack to a desired thickness.

12. A method according to claim 10, further comprising, after the gettering layer formation step before the gettering layer removing step, a step of annealing the composite substrate stack in one of a reducing atmosphere, an inert gas atmosphere, and a gas mixture atmosphere thereof.

13. A method according to claim 1, wherein in the bonded substrate stack preparation step, a porous layer is formed on the first substrate, and a transfer layer is formed on the porous layer to form the first substrate, and the first substrate and the second substrate are bonded to form the bonded substrate stack, and
the method further comprises after the annealing step, a step of separating the composite substrate stack at a portion of the porous layer.

14. A substrate manufacturing method comprising steps of:
preparing a first substrate which has an insulator at least on a surface and a second substrate in which a gettering layer to capture a metal contamination is formed on a surface;
bonding the first substrate and second substrate so as to arrange the gettering layer on a surface to form a composite substrate stack;
annealing the composite substrate stack; and
removing the gettering layer from the composite substrate stack.

15. A method according to claim 14, wherein in the preparation step, a porous layer is formed on the first substrate, and a transfer layer is formed on the porous layer to form the first substrate, and the method further comprises after the annealing step, a step of separating the composite substrate stack at a portion of the porous layer.
